(19) United States
(12) Patent Application Publication
(10) Pub. No.: US 2016/0231516 A1
(43) Pub. Date: Aug. 11, 2016

(54) Communication Module and Signal Transmission Device Including the Same

(71) Applicant: Hitachi Metals, Ltd., Tokyo (JP)

(72) Inventors: Yoshinori SUNAGA, Hitachinaka (JP); Kinya YAMAZAKI, Hitachi (JP); Yoshiaki ISHIGAMI, Hitachi (JP); Chihiro OHKUBO, Mito (JP)

(21) Appl. No.: 14/614,508

(22) Filed: Feb. 5, 2015

(51) Int. Cl. G02B 6/42; H05K 7/02; H05K 7/20; G02B 6/43

(52) U.S. Cl. CPC G02B 6/4214; G02B 6/43; G02B 6/4284; G02B 6/428; H05K 7/02; H05K 7/20418

(57) ABSTRACT

Space usable in various usages is ensured between a board and a communication module mounted on the board. A communication module is mounted on a motherboard inside a signal transmission device, and the communication module includes: a module frame having a lower plate and an upper plate facing each other and that contains a module board between the lower plate and the upper plate; and a male connector that is protruded from the lower plate and connected to a female connector provided in the motherboard. When the male connector is connected to the female connector, a gap is formed between the lower plate of the module frame and the motherboard.

### TECHNICAL FIELD OF THE INVENTION

The present invention relates to a communication module which is used in signal transmission between boards inside electronic devices and also used in signal transmission between such electronic devices, and a signal transmission device including the same.

### BACKGROUND OF THE INVENTION

A general signal transmission device includes a board on which a semiconductor element (IC chip) and a communication module are mounted. In the following descriptions, such aboard on which an IC chip and a communication module are mounted may be called as a “motherboard”.

An existing communication module includes a module frame. The module frame contains therein, a module board on which an IC, optical element, etc. are mounted. In addition, at the bottom surface of the module frame, a plurality of terminal pads are provided in a reticular pattern and electrically connected to the module board. Here, the bottom surface of the module frame means a surface that faces a mounting surface of a motherboard when the communication module is mounted onto the motherboard.

Upon mounting the communication module having such a structure on a motherboard, an interposer is disposed between the bottom surface of the module frame and the mounting surface of the motherboard. That is, the communication module and the motherboard are electrically connected via the interposer. Normally, the communication module stacked onto the interposer is pressed against the interposer by a spring.

### SUMMARY OF THE INVENTION

In the existing communication module, the terminal pads are provided in substantially the whole area of the bottom surface of the module frame. In addition, the communication module and the motherboard are electrically connected via the interposer disposed between the bottom surface of the module frame and the mounting surface of the motherboard. That is, there is almost no gap between the communication module and the motherboard. More specifically, there is almost no gap between the bottom surface of the module frame and the mounting surface of the motherboard.

Accordingly, the connection of the communication module and an optical fiber needs to be made at an upper surface (a surface opposite to the bottom surface) of the module frame. More specifically, an optical connector is needed to connect the communication module and the optical fiber and the optical connector is needed to be disposed on the upper surface of the module frame.

Meanwhile, the amount of heat generation of the communication modules is on the increase along with an increase of speed of signals inputted to and outputted from the communication modules. Thus, improvements of heat-dissipation efficiency and cooling efficiency of the communication modules are required.

However, when the existing communication module is mounted on the motherboard, there is almost no gap between the bottom surface of the module frame and the mounting surface of the motherboard and the optical connector is disposed on the upper surface of the module frame. Thus, an effective heat-dissipating surface in the surface of the module frame is small and the surface of the module frame is also difficult to receive cooling wind. That is, the heat-dissipation efficiency and cooling efficiency of the existing communication module are far from good.

Further, when a heatsink is disposed on the communication module, the heatsink is needed to be disposed clear of the optical connector that is disposed on the upper surface of the module frame. That is, in the upper surface of the module frame, an area to be thermally connected to the heatsink is limited to an area not covered with the optical connector.

An aim of the present invention is to ensure space between a board and a communication module mounted on the board, the space being usable in various usages such as heat dissipation, cooling, and cable connection.

A communication module according to the present invention is a communication module mounted on a board inside a signal transmission device, the communication module includes: a module frame having a lower plate and an upper plate facing each other and containing a module board between the lower plate and the upper plate; and a second connector that is protruded from the lower plate and connected to a first connector and provided in the board. In the communication module, when the second connector is connected to the first connector, a gap is formed between the lower plate of the module frame and the board.

According to an aspect of the present invention, a communication cable is led out from the lower plate of the module frame.

According to another aspect of the present invention, a light-emitting element provided in the module board, an optical fiber as the communication cable, and a connecting portion for changing a running direction of light emitted from the light-emitting element and letting the light enter the optical fiber are provided.

According to another aspect of the present invention, a light-receiving element provided in the module board, an optical fiber as the communication cable, and a connecting portion for changing the running direction of light emitted from the optical fiber and letting the light enter the light-receiving element are provided.

According to another aspect of the present invention, there is provided a metal plate disposed between the upper plate of the module frame and the module board, so that the light-emitting element is thermally connected to the module frame via the metal plate.

According to another aspect of the present invention, there is provided a metal plate disposed between the upper plate of the module frame and the module board, so that the light-receiving element is thermally connected to the module frame via the metal plate.

According to another aspect of the present invention, the optical fiber is connected to a part of the connection portion protruded from the lower plate.

According to another aspect of the present invention, the second connector has a protruding portion protruded from the lower plate and linearly extending along a side of the lower plate; and an electrode line, which is composed of a plurality of electrodes formed at a constant interval along a longitudinal direction of the protruding portion, is provided in each of a first side surface and a second side surface of the protruding portion, the second side surface facing the first side surface.

A signal transmission device of the present invention is a signal transmission device having a board on which a semiconductor element and a communication module are mounted, the communication module includes: a module frame having a lower plate and an upper plate facing each other and containing a module board between the lower plate and the upper plate; and a second connector that is protruded from the lower plate and connected to a first connector and provided in the board, and a gap is formed between the lower plate of the module frame and the board.

In an aspect of the present invention, a heatsink is mounted on the upper plate of the module frame of the communication module.

According to the present invention, between the board and the communication module mounted on the board, space usable in various usages such as heat dissipation, cooling, and cable connection is ensured.

### BRIEF DESCRIPTION OF THE DRAWINGS

FIG. 1 is an exploded perspective view illustrating an example of a signal transmission device to which the present invention is applied;

FIG. 2A is a plan view of the signal transmission device illustrated in FIG. 1;

FIG. 2B is a side view of the signal transmission device illustrated in FIG. 1;

FIG. 3A is an enlarged plan view of a communication module illustrated in FIG. 1;

FIG. 3B is an enlarged side view of the communication module illustrated in FIG. 1;

FIG. 3C is an enlarged bottom view of the communication module illustrated in FIG. 1;

FIG. 4 is an enlarged cross-sectional view of the communication module illustrated in FIG. 1;

FIG. 5 is an enlarged perspective view of a male connector and a female connector illustrated in FIG. 1;

FIG. 6A is a cross-sectional view of the male connector taken along the line A-A illustrated in FIG. 5;

FIG. 6B is a cross-sectional view of the female connector taken the line B-B illustrated in FIG. 5; and

FIG. 6C is a cross-sectional view illustrating a fitting state of the male connector and the female connector.

### DETAILED DESCRIPTION OF THE EMBODIMENTS

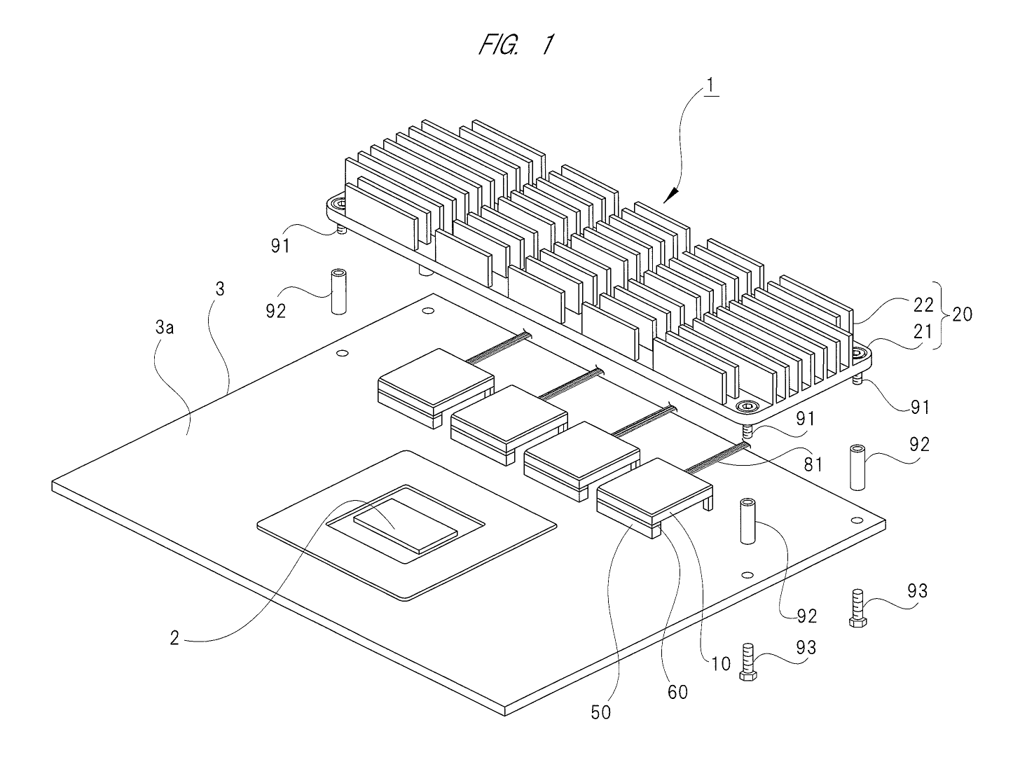

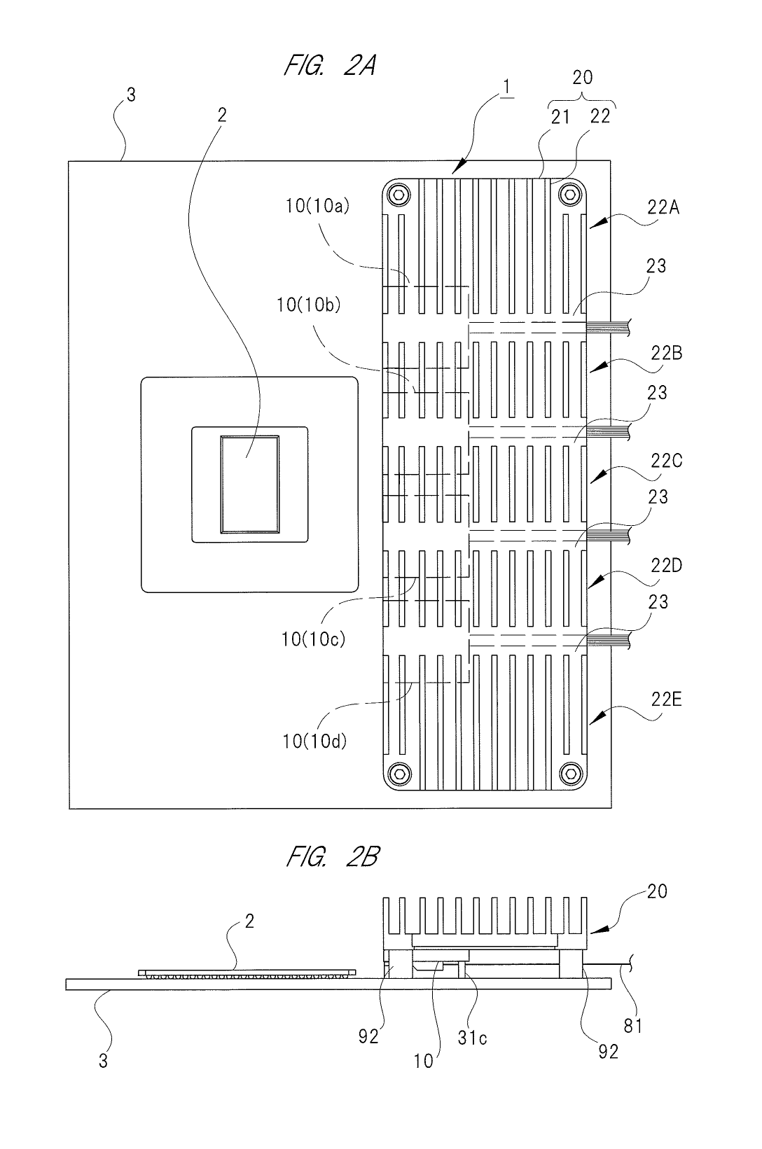

Hereinafter, an example of an embodiment of the present invention will be described with reference to the accompanying drawings. A signal transmission device 1 illustrated in FIGS. 1 to 2B includes a board (motherboard 3) for mounting a semiconductor element (IC chip 2) and a plurality of connection modules 10, and a heatsink 20 composing a cooling mechanism for cooling the communication modules 10. The heatsink 20 includes a heat-absorbing plate 21 having a substantially-rectangular shape in a plan view and a plurality of heat-dissipating fins 22 provided on the heat-absorbing plate 21. The heat-absorbing plate 21 and the heat-dissipating fins 22 are integrally formed using a metal (aluminum or copper) having a good heat conductivity.

In the present embodiment, near a side (longitudinal side) of the IC chip 2, four of the communication modules 10 are arranged in a line parallel to the side. Upon such a plurality of communication modules 10, the heatsink 20 is mounted such that a side (longitudinal side) of the heat-absorbing plate 21 is in parallel with the side of the IC chip 2.

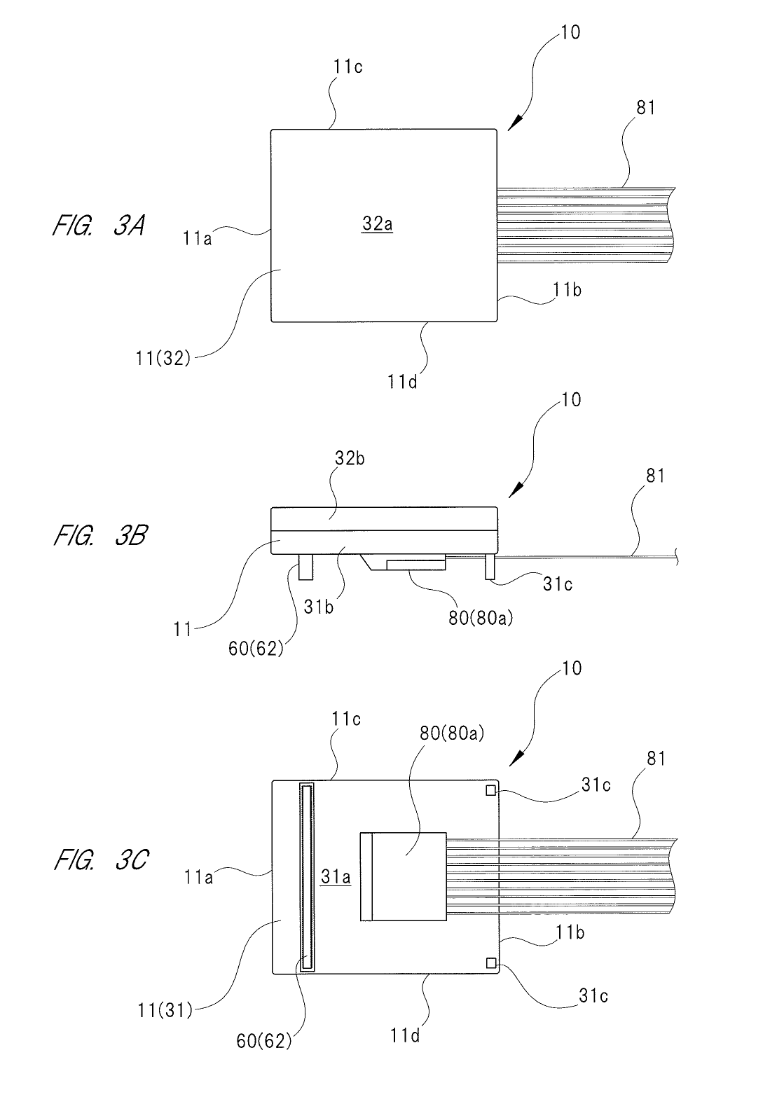

As illustrated in FIGS. 3A to 3C, each of the communication modules 10 has a module frame 11. The module frame 11 has two pairs of sides (sides 11a and lib and sides 11c and 11d) facing each other and its exterior appearance is substantially square in a plan view and a bottom view. Each length of the sides of the module frame 11 is 10 to 30 mm. However, the lengths of the module frame 11 can be optionally set and are not limited to the numeral range mentioned above. In addition, the shapes of the module frame 11 in a plan view and a bottom view are not limited to a square or a substantial square.

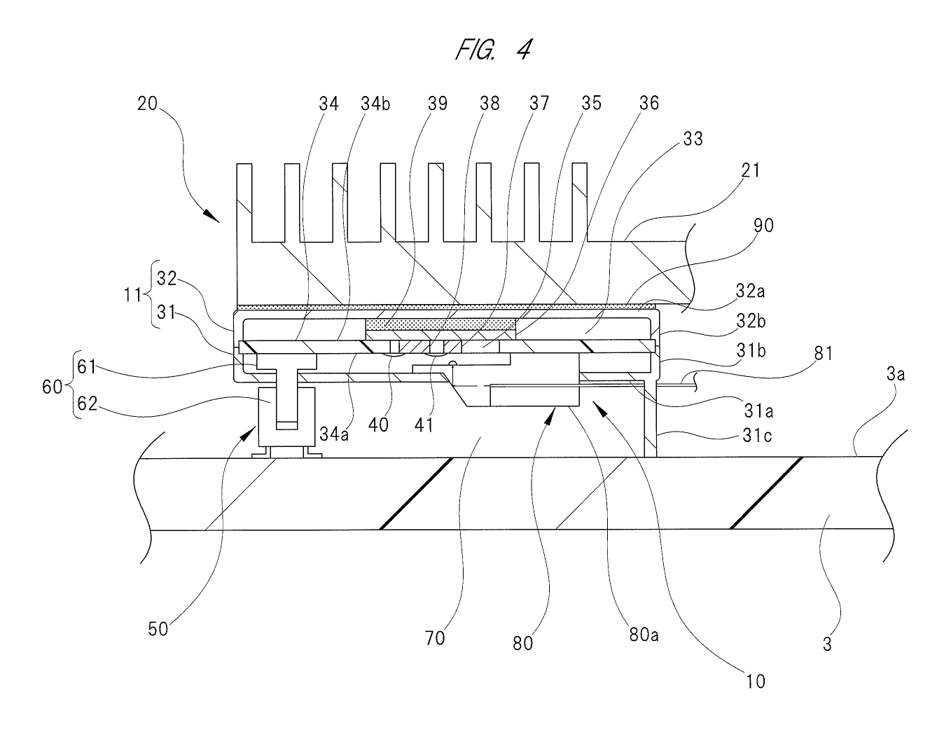

As illustrated in FIG. 4, the module frame 11 is composed of a first frame 31 and a second frame 32. The lower half of the module frame 11 is formed of the first frame 31 and the upper half of the module frame 11 is formed of the second frame 32.

The first frame 31 includes a lower plate 31a forming a bottom surface of the module frame 11, a sideplate 31b extended from an edge of the lower plate 31a to be substantially orthogonal to the lower plate 31a, and a supporting leg 31c extended from an external surface of the lower plate 31a in an opposite direction to the direction in which the side plate 31b is extended. That is, an inner surface of the lower plate 31a is surrounded by the side plate 31b. In addition, as illustrated in FIG. 3C, the supporting leg 31c is provided at each of two corners of an external surface of the lower plate 31a. In other words, the supporting leg 31c is provided at each of two corners of a bottom surface of the module fame 11. More specifically, one of the supporting legs 31c is provided near a cross section of the side lib and the side 11c of the module frame 11, and the other of the supporting legs 31c is provided near a cross section of the side 11b and the side 11d.

As illustrated in FIG. 4, the second frame 32 includes an upper plate 32a forming the upper surface of the module frame 11, and a side plate 32b extended from an edge of the upper plate 32a to be substantially orthogonal to the upper plate 32a. That is, an inner surface of the upper plate 32a is surrounded by the side plate 32b.

The first frame 31 and the second frame 32 are assembled such that both edge surfaces of the side plates 31b and 32b of the first and second frames 31 and 32 abut each other. A containing space 33 is formed between the first frame 31 and the second frame 32 facing each other. A module board 34 is contained in the containing space 33 of the module frame 11. The module board 34 is disposed to be parallel to the lower plate 31a of the first frame 31 and the upper plate 32a of the second frame 32. An edge of the module board 34 is sandwiched and supported between edge surfaces of the facing side plates of the first frame 31 and the second frame 32. The module board 34, which is in parallel with both of the lower plate 31a and the upper plate 32a, has a first surface facing the inner surface of the lower plate and a second surface facing the inner surface of the upper plate. That is, the module board 34 is contained between the lower plate 31a and the upper plate 32a of the module frame 11. In the following description, the first surface of the module board 34 will be called as a “back surface 34a” and the second surface of the module board 34 will be called as a “front surface 34b”.

At the substantially center of the module board 34, a rectangular opening portion 35 is formed. In addition, a metal plate 36 is attached to the front surface 34b of the module board 34, so that the opening portion 35 is closed by the metal plate 36. Inside the opening portion 35, a plurality of elements (light-emitting elements 37 in the present embodiment) and a plurality of driver ICs 38 for driving the light-emitting elements 37 are disposed. That is, the light-emitting elements 37 and the driver ICs 38 are mounted on the metal plate 36, and thermally connected to the metal plate 36. In other words, the light-emitting elements 37 and the driver ICs 38 are mounted on one of main surfaces of the metal plate 36. The entire of the other main surface of the metal plate 36 is in contact with the inner surface of the upper plate of the second frame 32 via a heat-conductive rubber 39 functioning as a heat conductive member. More specifically, the light-emitting elements 37 and the driver ICs 38 provided in the module boards 34 are thermally connected to the module frame 11, particularly to the upper plate 32a of the second frame 32, via the metal plate 36 and the heat conductive rubber 39.

Around the opening portion 35 of the module board 34, a plurality of electrode pads are formed. Each of the electrode pads is connected to a predetermined one of the driver ICs 38 via a bonding wire 40. In addition, each of the driver ICs 38 is connected to a predetermined one of the light-emitting elements 37 via a bonding wire 41. Here, by making a depth (thickness of the module board 34) of the opening 35 and heights of the driver IC 38 and the light element 37 substantially the same, lengths of the bonding wires 40 and 41 are made as short as possible.

At the back surface 34a of the module board 34, there is provided a second connector to be connected to a first connector that is provided in a mounting surface 3a of the motherboard 3. In the following description, the first connector provided in the motherboard 3 will be called as a “female connector 50”, and the second connector provided in the communication module 10 will be called as “a male connector 60”.

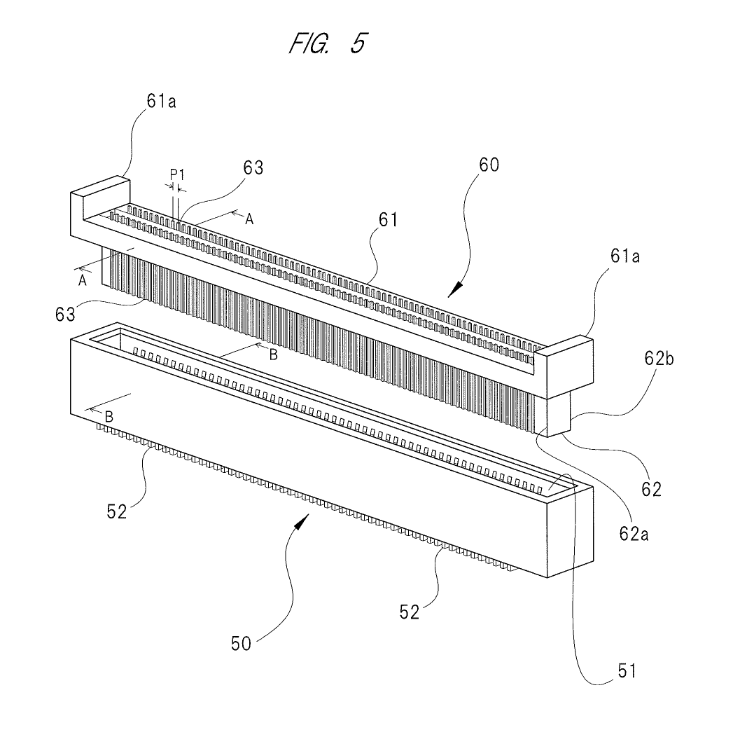

As illustrated in FIG. 5, the male connector 60 includes a base portion 61 fixed to the module board 34 (FIG. 4), and a protruding portion 62 extended from the base portion 61. The base portion 61 and the protruding portion 62 are integrally formed using a synthetic resin. At both ends in a longitudinal direction of the base portion 61, a positioning protrusion 61a is formed. An end portion of the module board 34 (FIG. 4) is fitted between the positioning protrusions 61a and 61a facing each other. The protruding portion 62 is extended from a lower surface of the base portion 61 to be orthogonal to the lower surface of the base portion 61. As illustrated in FIGS. 3C and 4, the protruding portion 62 of the male connector 60 is protruded to the outside from an opening portion provided in the lower plate 31a of the first frame 31. As illustrated in FIG. 3C, the protruding portion 62 protruded to the outside from the lower plate 31a of the first frame 31 is linearly extended along one side of the lower plate 31a. That is, the protruding portion 62 of the male connector 60 is protruded from the bottom surface of the module frame 11 and linearly extended along the side 11a of the module frame 11.

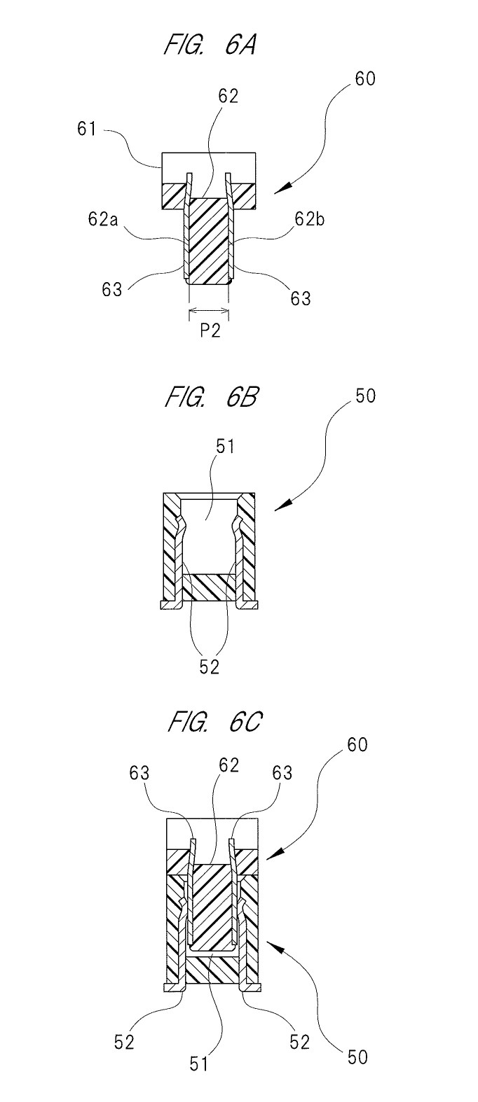

As illustrated in FIGS. 5 and 6A, the plurality of electrodes 63 are formed at a constant interval in the first side surface 62a of the protruding portion 62 and the second side surface 62b facing the first side surface 62a. In other words, in each of the first side surface 62a and the second side surface 62b, the electrode line formed of the plurality of electrodes 63 formed at a constant interval is provided. An end of each of the electrodes 63 penetrates the base portion 61 and protrudes from the upper surface of the base portion 61. The protruding end portion of each of the electrodes 63 is connected to the driver IC 38 via a printed wiring, which is not illustrated, formed in the module board 34 illustrated in FIG. 4.

Note that, to avoid crosstalk, some of the electrodes 63 formed in the protruding portion 62 are used as terminals for grounding. That is, not all of the electrodes 63 formed in the protruding portion 62 can be used as terminals for signal input/output. Thus, for not only avoiding crosstalk but also for inputting and outputting a large number of signals, it is needed to increase the total number of the electrodes 63. Meanwhile, the area of an electrode forming surface (first side surface 62a, second side surface 62b) of the protruding portion 62 is limited. Accordingly, it is needed to make the interval between the electrodes as narrow as possible. That is, it is needed to form the electrodes 63 at a narrow pitch. In the present embodiment, an interval (P1) between the electrodes illustrated in FIG. 5 is 0.5 mm and an interval (P2) between electrode lines illustrated in FIG. 6A is 1.5 mm.

As illustrated in FIG. 4, the male connector 60 having the above-described structure is fitted into the female connector 50 provided in the mounting surface 3a of the motherboard 3. As illustrated in FIGS. 5 and 6B, in the female connector 50, a fitting groove 51 is formed linearly along the longitudinal direction, the fitting groove 51 opening upwards and being capable of inserting thereto and removing therefrom the protruding portion 62 of the male connector 60. The plurality of electrodes 52 are provided inside the fitting groove 51. An end of each of the electrodes 52 penetrates a bottom portion of the fitting groove 51 and protrudes outside the fitting groove 51. A protruding end of each of the electrodes 52 is connected to the IC chip 2 via a printed wiring, which is not illustrated, formed in the motherboard 3 illustrated in FIG. 1.

As illustrated in FIG. 4, the communication module 10 is mounted on the motherboard 3 by fitting the male connector 60 into the female connector 50. In addition, as illustrated in FIG. 6C, when the male connector 60 is fitted into the female connector 50, the electrodes 63 and 52 provided in the respective connectors 60 and 50 are in contact with each other and electrically conducted. In this manner, the IC chip 2 and each of the communication modules 10 illustrated in FIG. 1 are electrically connected, so that transmission and reception of signals are enabled.

As illustrated in FIG. 4, when the male connector 60 is fitted into the female connector 50, the supporting leg 31c, which is extended from the bottom surface of the module frame 11, abuts the mounting surface 3a of the motherboard 3. In other words, the length of the supporting leg 31c is set to be the length that makes the supporting leg 31c abut the mounting surface of the motherboard 3 when the male connector 60 is fitted into the female connector 50. That is, the communication module 10 mounted on the motherboard 3 is supported by the supporting leg 31c and the male connector 60 that is protruded from the bottom surface (lower plate 31a of the first plate 31) of the module frame 11. In other words, the bottom surface of the module frame 11 has an area in which the male connector 60 protruded from the bottom surface is present, and an area in which the male connector 60 is not present. Thus, when the communication module 10 is mounted on the motherboard 3, that is, when the male connector 60 is fitted into the female connector 50, a gap 70 corresponding to the height of both the connectors 50 and 60 fitted together is formed between the mounting surface 3a of the motherboard 3 and the area in which the male connector 60 is not present in the bottom surface of the module frame 11. Thus, in comparison to the embodiment in which there is no gap between the bottom surface of the module frame 11 and the mounting surface 3a of the motherboard 3, the amount of heat dissipation from the bottom surface of the module frame 11 is increased. In addition, the bottom surface of the module frame 11 is easy to receive cooling wind. That is, the gap 70 is used as space for heat dissipation and cooling.

In addition, as illustrated in FIG. 3C, since the male connector 60 is provided near the side 11a of the module frame 11 and the supporting leg 31c is provided near both ends of the side 11b facing the side 11a, the communication module 10 is supported in a balanced manner.

Note that, between the female connector 50 and the male connector 60 which are connected as illustrated in FIG. 6C, there are a fitting length and an effective fitting length. The effective fitting length means a length included in the fitting length and also a length in a range capable of maintaining the electrical conduction between the female connector 50 and the male connector 60. That is, upon inserting the protruding portion 62 of the male connector 60 into the fitting groove 51 of the female connector 50, although the connectors 50 and 60 are physically fitted with each other in the beginning, they are not electrically conducted. Thereafter, when the protruding portion 62 of the male connector 60 is further inserted into the fitting groove 51 of the female connector 50, the connectors 50 and 60 are electrically conducted to each other. Further, since the effective length defines a length (e.g., 0.5 to 1.0 mm) to some extent, the electric conduction of the connectors 50 and 60 is maintained within that range even when the male connector 60 is inserted to and removed from the female connector 60. In other words, the male connector 60 fitted into the female connector 50 can be shifted to some extend in an upward and downward direction in the plane of the paper of FIG. 6 while maintaining the electric conduction with the female connector 60.

FIG. 4 is referred again. At the back surface 34a of the module board 34, an optical connector 80 as a connecting portion is provided in addition to the male connector 60. A part of the optical connector 80 is protruded to the outside of the lower plate 31a through the opening portion provided in the lower plate 31a of the first frame 31. In other words, a part of the optical connector 80 is exposed to the outside of the module frame 11. Accordingly, in the following description, the part of the optical connector 80 exposed to the outside of the lower plate 31a will be called as an “exposed portion 80a”. That is, the exposed portion 80a of the optical connector 80 is protruded to the gap 70 formed between the bottom surface (the lower plate 31a of the first frame 31) of the module frame 11 and the mounting surface 3a of the motherboard 3, and a plurality of communication cables (optical fibers 81) are connected to the exposed portion 80a. In other words, the optical fibers 81 connected to the module frame 11 via the optical connector 80 are led out around the module frame 11 through the gap 70.

However, there is an embodiment of disposing the whole optical connector inside a module frame. In such an embodiment, the optical fibers connected to the optical connector inside the module frame are led to the outside of the module frame from a side surface (for example, from the side plate 31b or the side plate 32b illustrated in FIG. 4) of the module frame. In this case, the portion from which the optical fibers are led out is covered by boots so as to protect the optical fibers. On the contrary, in the communication module 10 of the present embodiment in which the optical fibers 81 are connected to a part (exposed portion 80a) of the optical connector 80 protruded to the gap 70 that is formed between the motherboard 3 and the module frame 11, the boots is not needed and thus the cost can be reduced. In addition, in the communication module of the present embodiment, as compared to the embodiment in which the optical fibers are led out from the side surface of the module frame, the starting point of bending of the optical fibers 81, which are led out from the module frame 11, can be set near the module frame 11. Thus, the space necessary for handling the optical fibers 81 is reduced.

The optical connector 80 illustrated in FIG. 4 changes the running direction of light emitted from the light-emitting element 37 and letting the light enter an end surface of the optical fiber 81. That is, the light-emitting element 37 and the optical fiber 81 are optically coupled. More specifically, the optical connector 80 has a lens array and a mirror, so that the light emitted from the light-emitting element 37 and entered to the lens array is reflected on the mirror, and the light enters the end surface of the optical fiber 81. In the present embodiment, the running direction of the light, which is emitted from the light-emitting element 37 illustrated in FIG. 4 in a downward direction in the plane of the paper of FIG. 4, is converted by 90 degrees by the optical connector 80, and the light enters the end surface of the optical fiber 81.

As described above, in the present embodiment, the gap 70 is formed between the bottom surface of the module frame 11 and the mounting surface 3a of the motherboard 3. The gap 70 is used also as space for connecting the optical fibers 81 as communication cable.

As illustrated in FIGS. 1 and 4, on the communication module 10, the heatsink 20 is disposed. Particularly, as illustrated in FIG. 4, the heat-absorbing plate 21 of the heatsink 20 is stacked on the upper surface (the upper plate 32a of the second frame 32) of the module frame 11 interposing the heat-conductive rubber 90 as a heat conductive member. In the embodiment of connecting the module frame 11 and the optical fibers 81 using the gap 70 formed between the bottom surface of the module frame 11 and the mounting surface 3a of the motherboard 3, there is no convex or concave in an external surface of the upper plate of the second frame 32 forming the upper surface of the module frame 11. Thus, in the whole area, the external surface of the upper plate of the second frame 32 is thermally connected to the heat-absorbing plate 21 of the heatsink 20. Here, it has been already described that the light-emitting element 37 and the driver IC 38 are thermally connected to the upper plate 32a of the second frame 32 via the metal plate 36 and the heat-conductive rubber 39. That is, heat generated from the light-emitting element 37 and the driver IC 38 is efficiently transmitted to the heatsink 20 via the upper plate 32a of the second frame 32.

Note that, as illustrated in FIG. 1, the heatsink 20 mounted on the communication module 10 is fixed to the motherboard 3 by bolts 91 at four corners. More specifically, a cylindrical spacer 92 is disposed in each of between the heat-absorbing plate 21 of the heatsink 20 and the motherboard 3. A female screw is formed in each of the upper end surface and lower end surface of the spacers 92. The bolt 91, which penetrates the heat-absorbing plate 21 from above to below of the heat-absorbing plate 21, is coupled to the female screw formed in the upper end surface of the spacer 92. A bolt 93, which penetrates the motherboard 3 from below to above of the motherboard 3, is coupled to the female screw formed in the lower end of the spacer 92.

In addition, as illustrated in FIG. 2, each of the communication modules 10 is disposed across two heat-dissipating fin groups in a plan view. More specifically, the communication module 10a is disposed across the heat-dissipating fin group 22A and heat-dissipating fin group 22B. The communication module 10b is disposed across the heat-dissipating fin group 22B and heat-dissipating fin group 22C. The communication module 10c is disposed across the heat-dissipating fin group 22C and heat-dissipating fin group 22D. The communication module 10d is disposed across the heat-dissipating fin group 22D and heat-dissipating fin group 22E. That is, two heat-dissipating fin groups are allocated to one communication module 10.

Further, between adjacent ones of the heat-dissipating fin groups, each of gaps 23 is provided. Each of the gaps 23 plays a role of increasing cooling effect by generating turbulence between adjacent heat-dissipating fin groups.

The present invention is not limited to the above-described embodiment and various modifications and alterations can be made within the scope of the present invention. For example, although the male connector has been provided in the connection module and the female connector has been provided in the board in the above-described embodiment, the female connector can be provided in the communication module and the male connector can be provided in the board. The supporting leg for supporting the communication module can be integrally formed with the board. Moreover, a member being independent with respect to the communication module and the board can be disposed as a supporting leg, between the communication module and the board.

In the above-described embodiment, the light-emitting element and the driver IC are mounted on the module board. That is, the communication module according to the above-described embodiment is used for transmission. However, a light-receiving element and an amplifying IC maybe mounted on the module board. That is, a communication module for reception and a signal transmission device including the same are included in the present invention. In addition, on the module board, a light-emitting element and a driver IC, and a light-receiving element and an amplifying IC may be mounted. That is, the communication module for transmission and reception and a signal transmission device including the same are included in the present invention. Moreover, the present invention may include such a case that a semiconductor element (IC) is mounted on the module board and the semiconductor element and a metal wire are connected via a connection portion. In this case, as the connection portion, an electrical connector having a predetermined function (e.g., waveform rectifying function) is used. That is, an active transmission module having an IC is included in the present invention.

While the heatsink in the above-described embodiment is an air-cooling type heatsink having a heat-absorbing plate and a heat-dissipating fin, the heatsink may be replaced by a water-cooling heatsink having a heat-absorbing plate and a coolant path.

The heat-conductive rubber in the above-described embodiment may be replaced by a heat-conductive sheet and grease having a good heat conductivity, etc.

A plurality of communication modules may be disposed so as to surround the four sides of a semiconductor element (IC chip) mounted on the board. Moreover, a plurality of communication modules may be disposed along two or three sides of the semiconductor element (IC chip).

1. A communication module mounted on a board of a signal transmission device, the communication module comprising:
a module frame having a lower plate and an upper plate facing each other and containing a module board between the lower plate and the upper plate; and
a second connector that is protruded from the lower plate and connected to a first connector provided in the board, wherein
the first connector and the second connector are a connector pair including a male connector and a female connector fitted and connected to each other,
when the second connector is connected to the first connector, a gap corresponding to a height of the first connector and the second connector fitted to each other is formed between the lower plate of the module frame and the board, and
the gap is open in at least two directions parallel to a surface of the board.

2. The communication module according to claim 1, wherein a communication cable is led out from the lower plate of the module frame.

3. The communication module according to claim 2, further comprising:
a light-emitting element provided in the module board;
an optical fiber as the communication cable; and
a connecting portion for changing a running direction of light emitted from the light-emitting element and letting the light enter the optical fiber.

4. The communication module according to claim 2, further comprising:
a light-receiving element provided in the module board;
an optical fiber as the communication cable; and
a connecting portion for changing a running direction of light emitted from the optical fiber and letting the light enter the light-receiving element.

5. The communication module according to claim 3, further comprising a metal plate disposed between the upper plate of the module frame and the module board, wherein the light-emitting element is thermally connected to the module frame via the metal plate.

6. The communication module according to claim 4, further comprising a metal plate disposed between the upper plate of the module frame and the module board, wherein the light-receiving element is thermally connected to the module frame via the metal plate.

7. The communication module according to claim 3, wherein the optical fiber is connected to a part of the connection portion protruded from the lower plate.

8. The communication module according to claim 4, wherein the optical fiber is connected to a part of the connection portion protruded from the lower plate.

9. The communication module according to claim 1, wherein the second connector has a protruding portion protruded from the lower plate and linearly extending along a side of the lower plate, and an electrode line, which is composed of a plurality of electrodes formed at a constant interval along a longitudinal direction of the protruding portion, is provided in each of a first side surface and a second side surface of the protruding portion, the second side surface facing the first side surface.

10. A signal transmission device including a board on which a semiconductor element and a communication module are mounted, wherein the communication module comprises:
a module frame having a lower plate and an upper plate facing each other and containing a module board between the lower plate and the upper plate; and
a second connector that is protruded from the lower plate and connected to a first connector provided in the board, and wherein
the first connector and the second connector are a connector pair including a male connector and a female connector fitted and connected to each other,
when the second connector is connected to the first connector, a gap corresponding to a height of the first connector and the second connector fitted to each other is formed between the lower plate of the module frame and the board, and
the gap is open in at least two directions parallel to a surface of the board.

11. The signal transmission device according to claim 10, further comprising a heatsink mounted on the upper plate of the module frame of the communication module.
